(19) United States
(12) Patent Application Publication
(10) Pub. No.: US 2026/0155177 A1
(43) Pub. Date: Jun. 4, 2026

(54) THREE-DIMENSIONAL MEMORY DEVICE INCLUDING SILICON OXYNITRIDE AND DIPOLE-CONTAINING BLOCKING DIELECTRIC LAYER AND METHODS FOR FORMING THE SAME

(71) Applicant: Sandisk Technologies, Inc., Milpitas, CA (US)

(72) Inventor: Takashi YUDA, Yokkaichi (JP)

(21) Appl. No.: 18/966,778

(22) Filed: Dec. 3, 2024

(51) Int. Cl. G11C 16/04; H10B 43/10; H10B 43/27; H10B 43/35

(52) U.S. Cl. CPC G11C 16/0483; H10B 43/10; H10B 43/27; H10B 43/35

(57) ABSTRACT

A memory device includes an alternating stack of insulating layers and electrically conductive layers, a memory opening vertically extending through the alternating stack, and

a memory opening fill structure located in the memory opening and including, from outside to inside, a silicon oxide blocking dielectric layer, a silicon oxynitride blocking dielectric layer, an inner dielectric metal oxide blocking dielectric layer, a memory material layer, a tunneling dielectric layer, and a vertical semiconductor channel.

### FIELD

The present disclosure relates generally to the field of semiconductor devices, and particularly to a three-dimensional memory device including silicon oxynitride and dipole-containing blocking dielectric layers and methods of manufacturing the same.

### BACKGROUND

Three-dimensional vertical NAND memory structures with one bit per cell are described in an article by T. Endoh et al., titled “Novel Ultra High-Density Memory With A Stacked-Surrounding Gate Transistor (S-SGT) Structured Cell,” IEDM Proc. (2001) 33-36.

### SUMMARY

According to an aspect of the present disclosure, a memory device comprises: an alternating stack of insulating layers and electrically conductive layers; a memory opening vertically extending through the alternating stack; and a memory opening fill structure located in the memory opening and comprising, from outside to inside, a silicon oxide blocking dielectric layer, a silicon oxynitride blocking dielectric layer, an inner dielectric metal oxide blocking dielectric layer, a memory material layer, a tunneling dielectric layer, and a vertical semiconductor channel.

According to another aspect of the present disclosure, a method of forming a memory device comprises: forming an alternating stack of insulating layers and spacer material layers over a carrier substrate, wherein the spacer material layers are formed as, or are subsequently replaced with, electrically conductive layers; forming a memory opening through the alternating stack; and forming a memory opening fill structure in the memory opening by sequentially forming a silicon oxide blocking dielectric layer, a silicon oxynitride blocking dielectric layer, an inner dielectric metal oxide blocking dielectric layer, a memory material layer, a tunneling dielectric layer, and a vertical semiconductor channel.

### BRIEF DESCRIPTION OF THE DRAWINGS

FIG. 1 is a schematic vertical cross-sectional view of a first exemplary structure after formation of an alternating stack of insulating layers and sacrificial material layers over a carrier substrate according to an embodiment of the present disclosure.

FIG. 2 is a schematic vertical cross-sectional view of the first exemplary structure after formation of stepped surfaces and a stepped dielectric material portion according to an embodiment of the present disclosure.

FIG. 3A is a schematic vertical cross-sectional view of the first exemplary structure after formation of memory openings and support openings according to an embodiment of the present disclosure. FIG. 3B is a top-down view of the first exemplary structure of FIG. 3A. The hinged vertical cross-sectional plane A-A′ is the cut plane of the vertical cross-sectional view of FIG. 3A.

FIG. 4 is a schematic vertical cross-sectional view of the first exemplary structure after formation of sacrificial opening fill structures according to an embodiment of the present disclosure.

FIG. 5 is a vertical cross-sectional view of the first exemplary structure after formation of support pillar structures according to an embodiment of the present disclosure.

FIG. 6 is a schematic vertical cross-sectional view of the first exemplary structure after removal of sacrificial memory opening fill structures according to an embodiment of the present disclosure.

FIGS. 7A-7F are sequential vertical cross-sectional views of a memory opening within the first exemplary structure during formation of a memory opening fill structure according to an embodiments of the present disclosure.

FIG. 8A is a schematic vertical cross-sectional view of the first exemplary structure after formation of memory opening fill structures according to an embodiment of the present disclosure. FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of lateral isolation trenches according to an embodiment of the present disclosure.

FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of laterally-extending cavities according to an embodiment of the present disclosure.

FIG. 11 is a schematic vertical cross-sectional view of the first exemplary structure after formation of electrically conductive layers according to an embodiment of the present disclosure.

FIG. 12A is a vertical cross-sectional view of the first exemplary structure after formation of lateral isolation trench fill structures, layer contact via structures, and drain contact via structures according to an embodiment of the present disclosure. FIG. 12B is a top-down view of the first exemplary structure of FIG. 12A. The vertical plane A-A is the cut plane of the vertical cross-sectional view of FIG. 12A.

FIG. 13 is a vertical cross-sectional view of the first exemplary structure after formation of a memory die according to an embodiment of the present disclosure.

FIG. 14 is a vertical cross-sectional view of a logic die according to an embodiment of the present disclosure.

FIG. 15 is a vertical cross-sectional view of the first exemplary structure after attaching the logic die to the memory die according to an embodiment of the present disclosure.

FIG. 16A is a vertical cross-sectional view of the first exemplary structure after removal of the carrier substrate according to an embodiment of the present disclosure. FIG. 16B is a magnified view of a region of the first exemplary structure of FIG. 16A.

FIGS. 17A and 17B are sequential vertical cross-sectional views of a region of the first exemplary structure during formation of a source layer according to an embodiment of the present disclosure.

FIG. 18 is a vertical cross-sectional view of the first exemplary structure after formation of the source layer according to an embodiment of the present disclosure.

FIG. 19 is a vertical cross-sectional view of the first exemplary structure after formation of a backside insulating layer and at least one source contact structure according to an embodiment of the present disclosure.

FIGS. 20A-20F are sequential vertical cross-sectional views of a memory opening within a second exemplary structure during formation of a memory opening fill structure according to an embodiments of the present disclosure.

FIGS. 21A-21C are sequential vertical cross-sectional views of a region of the second exemplary structure after removal of the carrier substrate and during formation of a source layer according to an embodiment of the present disclosure.

FIG. 22 is a vertical cross-sectional view of the second exemplary structure after formation of a backside insulating layer and at least one source contact structure according to an embodiment of the present disclosure.

FIG. 23 is a bar graph of normalized oxygen areal density for various oxide dielectric materials.

FIGS. 24A and 24B are band diagram of various layers within and around a memory opening fill structure according to an embodiment of the present disclosure and according to a comparative example, respectively.

### DETAILED DESCRIPTION

As discussed above, the embodiments of the present disclosure are directed to a three-dimensional memory device including silicon oxynitride and dipole-containing blocking dielectric layers and methods of manufacturing the same, the various aspects of which are described below. Embodiments of the disclosure can be employed to form various structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a surface of a structural element has a “convex profile” in a cross-sectional view if the surface is contoured such that a center of curvature of a curved segment of the surface is located on a side of the structural element relative to the surface of the structural element in the cross-sectional view. As used herein, a surface of a structural element has a “concave profile” in a cross-sectional view if the surface is contoured such that a center of curvature of a curved segment of the surface is located on an opposite side of the structural element relative to the surface of the structural element in the cross-sectional view. As used herein, a surface of a structural element is a “convex surface” if the surface has a convex profile in a cross-sectional view. A surface is a “vertically-convex surface” if the surface has a convex profile in a vertical cross-sectional view. A surface is a “vertically-concave surface” if the surface has a convex profile in a vertical cross-sectional view. A surface is a “vertically-straight surface” if the surface has no curvature in a vertical cross-sectional view. A surface is a “horizontally-convex surface” if the surface has a convex profile in a horizontal cross-sectional view. A surface is a “horizontally-concave surface” if the surface has a concave profile in a vertical cross-sectional view. A surface is a “horizontally-straight surface” if the surface has no curvature in a horizontal cross-sectional view. Generally, convexity or concavity in a vertical cross-sectional view is independent of convexity or concavity in a horizontal cross-sectional view.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

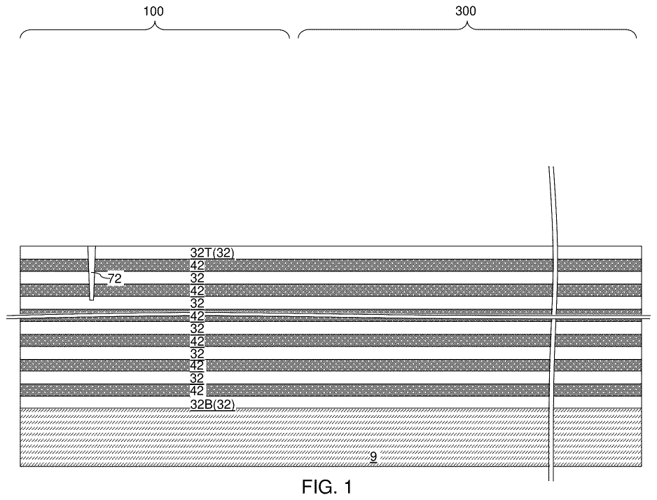

Referring to FIG. 1, a first exemplary structure according to an embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selectively to the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser or greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser or greater thicknesses may also be employed. Each of the sacrificial material layers 42 may have a thickness in a range from 20 nm to 100 nm, such as from 30 nm to 60 nm, although lesser or greater thicknesses may also be employed. In one embodiment, the topmost insulating layer 32T may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed. Drain-select-level isolation structures 72 laterally extending along a first horizontal direction hd1 may be formed through a subset of the uppermost sacrificial material layers 42 that will be replaced with drain side select gate electrodes.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

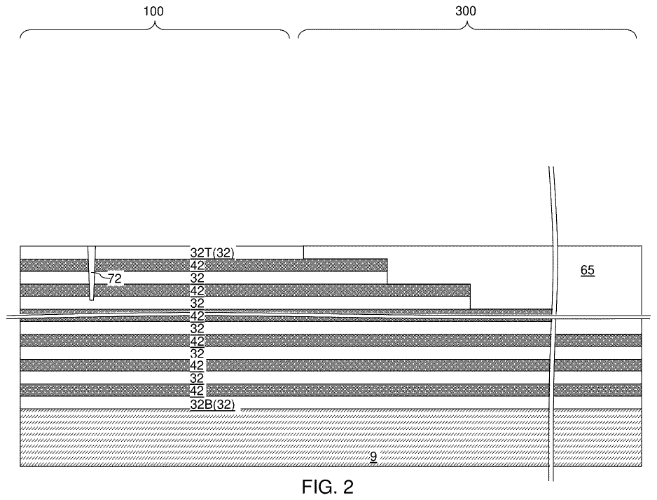

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

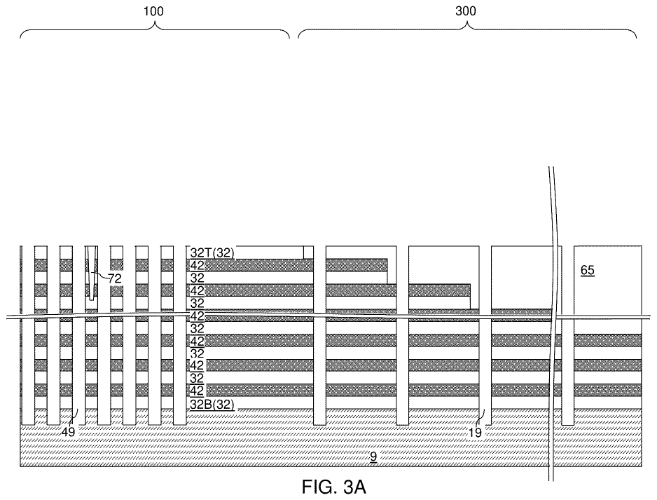

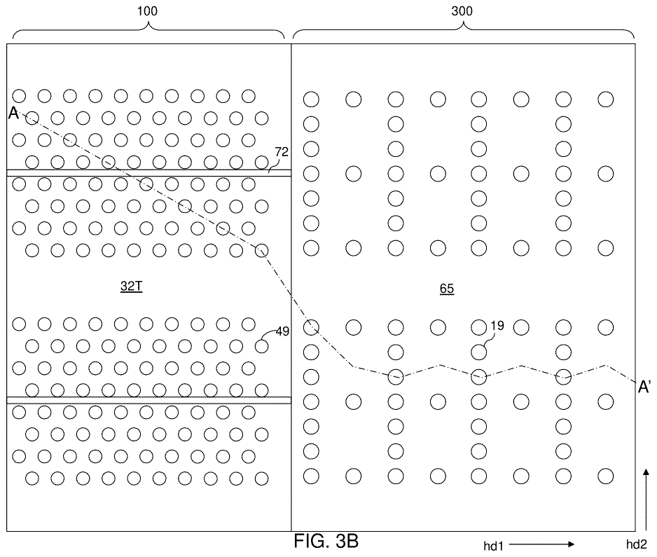

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser or greater thicknesses may be employed. The support openings 19 may have a diameter in a range from 60 nm to 400 nm, such as from 120 nm to 300 nm, although lesser or greater thicknesses may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (e.g., the word line direction) with a uniform pitch. The rows of memory openings 49 may be laterally spaced from each other along the second horizontal direction hd2 (e.g., the bit line direction), which may be perpendicular to the first horizontal direction hd1. In one embodiment, each cluster of memory openings 49 may be formed as a two-dimensional periodic array of memory openings 49.

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fill a support opening 19 constitutes a sacrificial support opening fill structure 18.

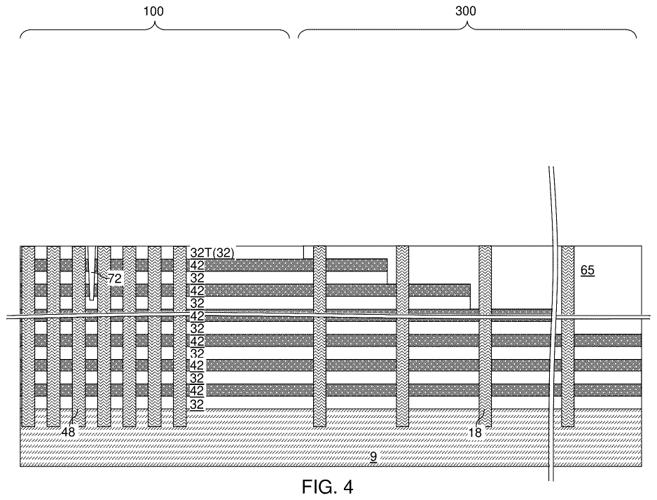

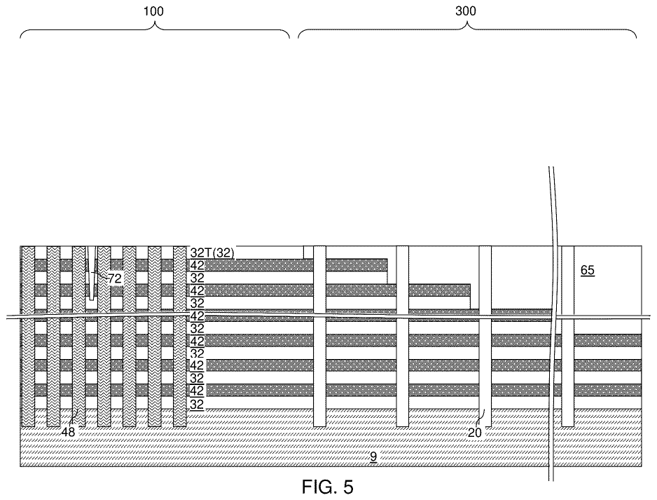

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selectively to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

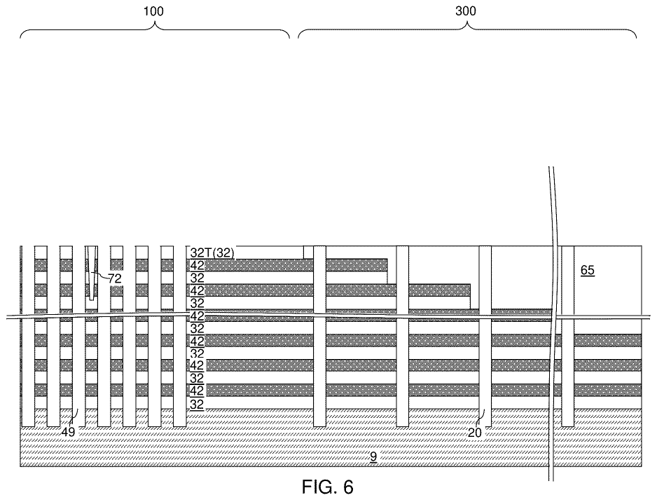

Referring to FIG. 6, sacrificial memory opening fill structures 48 are subsequently removed selectively to the materials of the insulating layers 32, the sacrificial material layers 42, and the carrier substrate 9. Voids are formed in the volumes of the memory openings 49 from which the sacrificial memory opening fill structures 48 are removed.

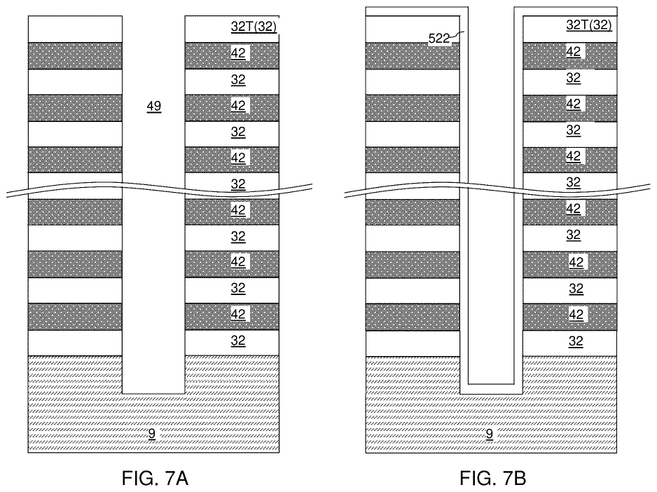

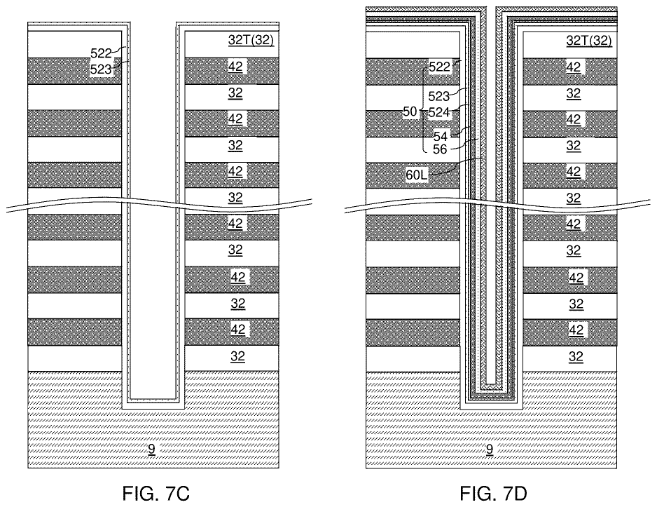

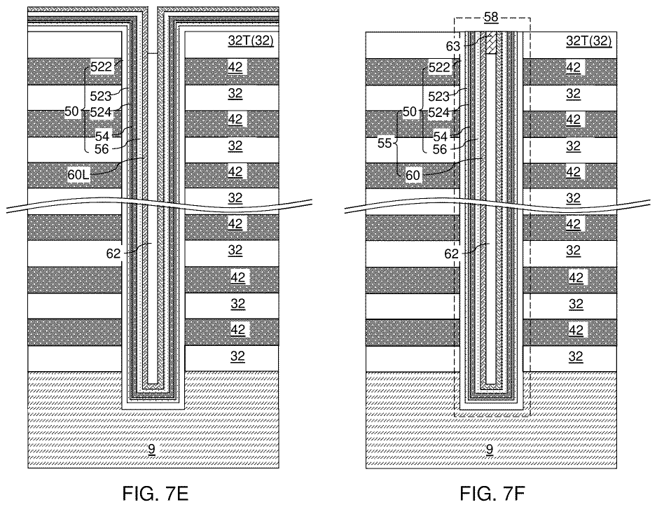

FIGS. 7A-7F are sequential vertical cross-sectional views of a memory opening 49 during formation of a memory opening fill structure 58 according to an embodiments of the present disclosure.

Referring to FIG. 7A, a memory opening 49 is illustrated after the processing steps of FIG. 6. Generally, an alternating stack of insulating layers 32 and spacer material layers (which may comprise the sacrificial material layers 42) can be formed over a carrier substrate 9. The spacer material layers are formed as, or are subsequently replaced with, electrically conductive layers. The memory openings 49 are formed through the alternating stack, and may extend to or below a top surface of the carrier substrate 9.

Referring to FIG. 7B, a silicon oxide blocking dielectric layer 522 can be deposited in each memory opening 49 by performing a conformal deposition process. The silicon oxide blocking dielectric layer 522 may consist essentially of silicon and oxygen and residual hydrogen and/or carbon, and may be deposited by atomic layer deposition and/or chemical vapor deposition, using any suitable precursors, such as tetraethylorthosilicate, or a combination of silane (e.g., monosilane, disilane, chlorosilane or organosilane) and an oxygen source gas, such as nitrous oxide, fluorine nitrate, oxygen, etc. The silicon oxide blocking dielectric layer 522 may be deposited with a uniform thickness, which may be in a range from 5 nm to 20 nm, such as from 7 nm to 10 nm, although lesser or greater thicknesses may also be employed. Alternatively, if the silicon oxide blocking dielectric layer 522 comprises an in-process silicon oxide blocking dielectric layer 522 whose inner portion is converted to silicon oxynitride by nitridation, then the in-process silicon oxide blocking dielectric layer 522 thickness may be in a range from 7 nm to 30 nm, such as from 8 nm to 12 nm, although lesser or greater thicknesses may also be employed.

Referring to FIG. 7C, a silicon oxynitride blocking dielectric layer 523 is formed over the silicon oxide blocking dielectric layer 522. The thickness of the silicon oxynitride blocking dielectric layer 523 may be in a range from 1 nm to 5 nm, such as from 2 nm to 4 nm, although lesser or greater thicknesses may also be employed.

In one embodiment, the silicon oxynitride blocking dielectric layer is deposited by chemical vapor deposition and/or atomic layer deposition on the silicon oxide blocking dielectric layer 522. For example, low pressure chemical vapor deposition using a mixture of a chlorosilane, nitrous oxide and ammonia precursor gases may be used to deposit the silicon oxynitride blocking dielectric layer 523. Alternatively, plasma enhanced chemical vapor deposition or electron cyclotron resonance chemical vapor deposition using silane and either oxygen or nitrous oxide, and ammonia or nitrogen precursors may be used to deposit the silicon oxynitride blocking dielectric layer 523.

In another embodiment, a nitridation process can be performed to nitride an inner surface portion of the in-process silicon oxide blocking dielectric layer 522 to form the silicon oxynitride blocking dielectric layer 523 Specifically, a surface nitridation process can be performed on the physically exposed surfaces of the in-process silicon oxide blocking dielectric layer 522. For example, the first exemplary structure can be located into a vacuum furnace, and a nitrogen containing gas or plasma, such as ammonia can be flowed into the vacuum furnace at an elevated temperature, which may be in a range from 600 degrees Celsius to 900 degrees Celsius. The process temperature and the duration of the nitridation process can be selected such that an outer portion of the in-process silicon oxide blocking dielectric layer 522 is not nitrided during the nitridation process while an inner portion of the in-process silicon oxide blocking dielectric layer 522 is nitrided. The outer portion of the in-process silicon oxide blocking dielectric layer 522 that is not nitrided constitutes the completed silicon oxide blocking dielectric layer 522, and the inner portion of the in-process silicon oxide blocking dielectric layer 522 that is nitrided constitutes the silicon oxynitride blocking dielectric layer 523.

The nitrogen atoms diffuse inward from the physically exposed surfaces of the in-process silicon oxide blocking dielectric layer 522 during the nitridation process. Thus, the atomic concentration of nitrogen atoms in the silicon oxynitride blocking dielectric layer 523 decreases with a distance from the physically exposed surfaces of the silicon oxynitride blocking dielectric layer 523 within the volumes of the silicon oxynitride blocking dielectric layer 523. The vertically extending portions of the silicon oxynitride blocking dielectric layer 523 have a radial atomic nitrogen concentration gradient between an interface with the silicon oxide blocking dielectric layer 522 and the physically exposed vertically-extending surfaces of the vertically extending portions of the silicon oxynitride blocking dielectric layer 523. In one embodiment, the nitrogen concentration in the vertically-extending portions of the silicon oxynitride blocking dielectric layer 523 decreases with a distance from the physically exposed vertically-extending sidewalls of the silicon oxynitride blocking dielectric layer 523. In one embodiment, the nitrogen concentration in the silicon oxynitride blocking dielectric layer 523 may be zero at an interface with the silicon oxide blocking dielectric layer 522.

The silicon oxynitride blocking dielectric layer 523 may have a formula SiNₓO_{y} in which both x and y are greater than zero. For example, the silicon oxynitride blocking dielectric layer 523 may include at least 15 atomic percent nitrogen and at least 15 atomic percent oxygen at the physically exposed surfaces of the silicon oxynitride blocking dielectric layer 523 In one embodiment, the nitrogen concentration in the silicon oxynitride blocking dielectric layer 523 at the physically exposed surfaces of the silicon oxynitride blocking dielectric layer 523 may be in a range from 15 atomic percent to 40 atomic percent.

Referring to FIG. 7D, a layer stack including an inner dielectric metal oxide blocking dielectric layer 524, a memory material layer 54, a tunneling dielectric layer 56, and a semiconductor channel material layer 60L can be sequentially deposited. The inner dielectric metal oxide blocking dielectric layer 524 comprises a dielectric metal oxide material that can generate a dipole moment at an interface with the silicon oxynitride blocking dielectric layer 523. In one embodiment, the inner dielectric metal oxide blocking dielectric layer 524 comprises and/or consists essentially of aluminum oxide (e.g., Al₂O₃). Alternatively, the inner dielectric metal oxide blocking dielectric layer 524 comprises and/or consists essentially of hafnium oxide. The thickness of the inner dielectric metal oxide blocking dielectric layer 524 may be in a range from 0.4 nm to 3 nm, such as from 0.5 nm to 2 nm, although lesser or greater thicknesses may also be employed. The inner dielectric metal oxide blocking dielectric layer 524 may be formed by a conformal deposition process, such as an atomic layer deposition process, using one to four alternating cycles of aluminum tetrachloride and ozone pulses. According to an aspect of the present disclosure, use of the silicon oxynitride blocking dielectric layer 523 in direct contact with the inner dielectric metal oxide blocking dielectric layer 524 increases the oxygen density gradient across the interface between the silicon oxynitride blocking dielectric layer 523 and the inner dielectric metal oxide blocking dielectric layer 524 relative to a configuration in which the inner dielectric metal oxide blocking dielectric layer 524 contacts a higher oxygen areal density dielectric material, such as silicon oxide. In one embodiment, an inner sidewall of the silicon oxynitride blocking dielectric layer 523 is in direct contact with an outer sidewall of the inner dielectric metal oxide blocking dielectric layer 524 within each memory opening 49.

Subsequently, a memory material layer 54 can be conformally deposited. The memory material layer 54 includes a memory material, i.e., a material that can store data bits therein. In one embodiment, the memory material layer 54 may comprise, and/or may consist essentially of, a charge storage material, such as silicon nitride. The memory material layer 54 may be deposited by a conformal deposition process such as a chemical vapor deposition process. The thickness of the memory material layer 54 may be in a range from 3 nm to 10 nm, such as from 4 nm to 8 nm, although lesser or greater thicknesses may also be employed.

The tunneling dielectric layer 56 can be deposited on the memory material layer 54. The tunneling dielectric layer 56 may comprise any tunneling dielectric material known in the art. For example, the tunneling dielectric layer 56 may comprise an ONO stack (i.e., a layer stack including a first silicon oxide layer, a silicon nitride layer, and a second silicon nitride layer) having a thickness in a range from 2 nm to 3 nm, although lesser or greater thicknesses may also be employed.

The combination of the silicon oxide blocking dielectric layer 522, the silicon oxynitride blocking dielectric layer 523, the inner dielectric metal oxide blocking dielectric layer 524, the memory material layer 54, and the tunneling dielectric layer 56 is herein referred to as a memory film 50.

The semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser or greater thicknesses may also be employed. In one embodiment, the semiconductor channel material layer 60L includes first electrical dopants of a first conductivity type at a first atomic concentration, which may be in a range from 1.0×10¹³/cm³ to 1.0×10¹⁶/cm³, although lesser or greater atomic concentrations may also be employed.

Referring to FIG. 7E, a dielectric core layer comprising a dielectric fill material, such as silicon oxide, can be deposited in remaining volumes of the memory openings 49. While the dielectric core layer can be deposited employing a conformal deposition process, such as a chemical vapor deposition process, the conformity of the conformal deposition process may not be perfect. Thus, the thickness of a bottom portion of the dielectric core layer at the bottom of each memory opening 49 may be less than the thickness of an upper portion of the dielectric core layer at the top of each memory opening 49. The dielectric core layer can be subsequently vertically recessed such that each remaining portion of the dielectric core layer has a top surface at, or about, the horizontal plane including the bottom surface of the topmost insulating layer 32T. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser or greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60. In one embodiment, each vertical semiconductor channel 60 includes first electrical dopants of a first conductivity type at the first atomic concentration. Alternatively, the vertical semiconductor channel 60 may be undoped (i.e., intrinsic).

Each portion of the layer stack including the memory material layer 54 that remains in a respective memory opening 49 constitutes a memory film 50. In one embodiment, a memory film 50 may comprise a blocking dielectric layer stack including a silicon oxide blocking dielectric layer 522, a silicon oxynitride blocking dielectric layer 523, and an inner dielectric metal oxide blocking dielectric layer 524; a memory material layer 54; and a tunneling dielectric layer 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 can be formed in a respective memory opening 49 by sequentially forming the silicon oxide blocking dielectric layer 522, the silicon oxynitride blocking dielectric layer 523, the inner dielectric metal oxide blocking dielectric layer 524, the memory material layer 54, a tunneling dielectric layer 56, and the vertical semiconductor channel 60. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extend predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

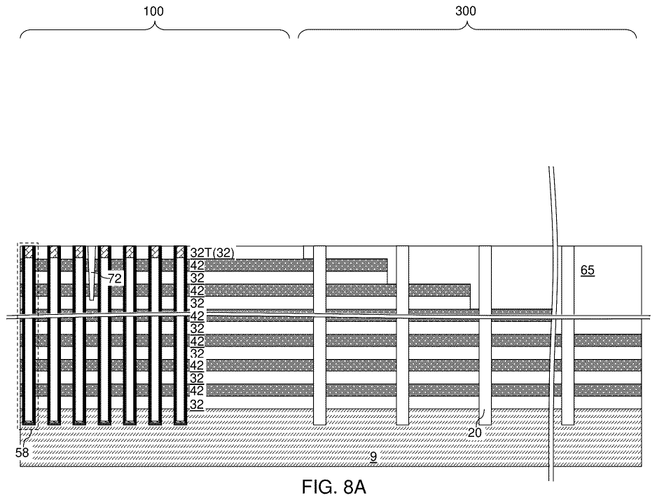

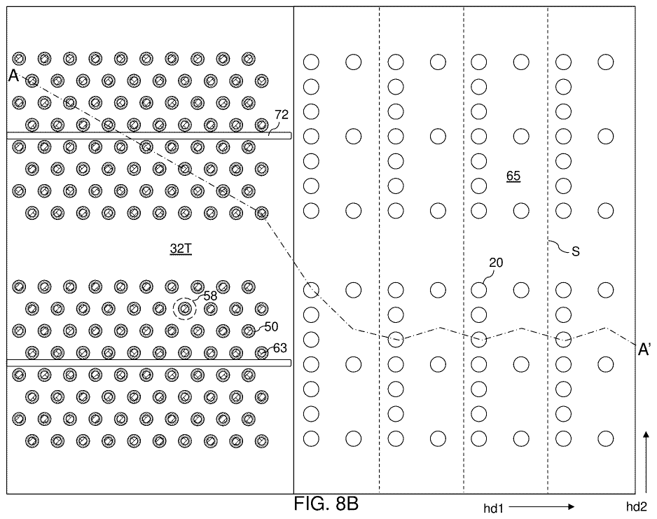

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

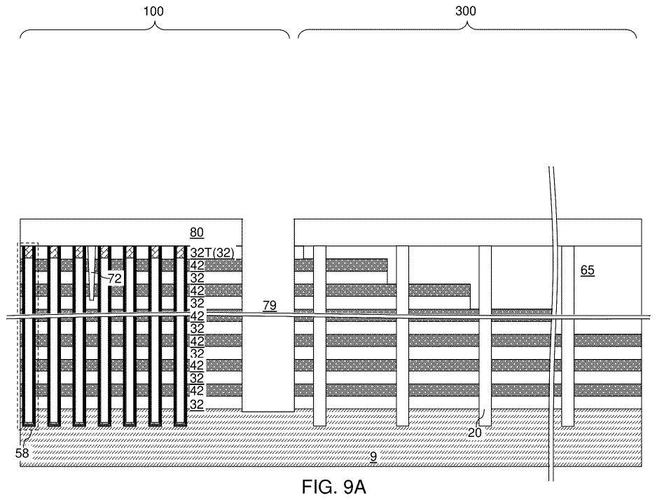

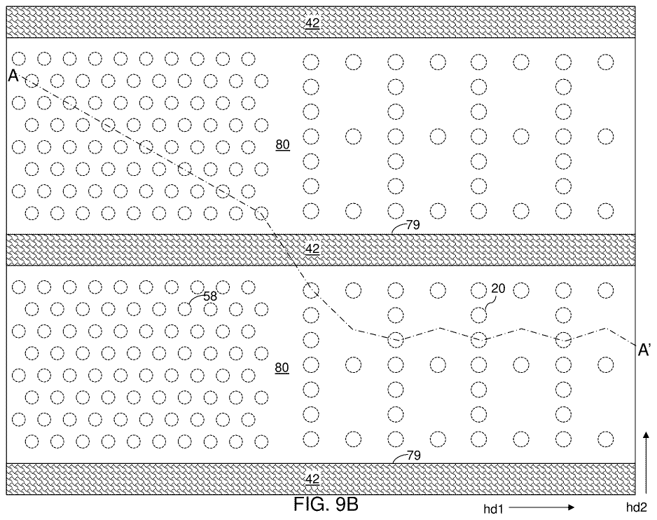

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser or greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

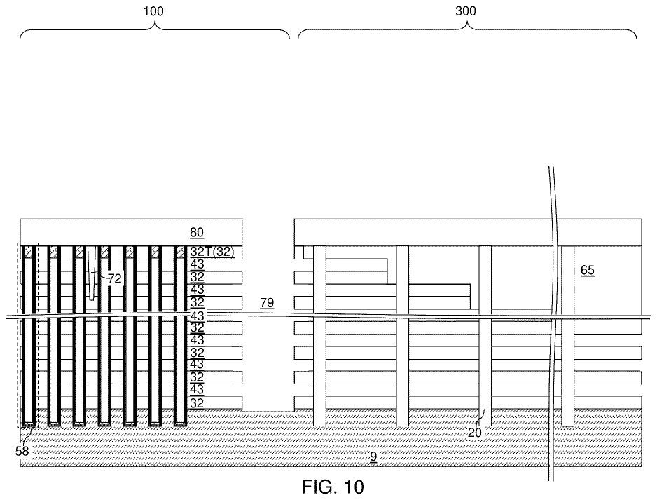

Referring to FIG. 10, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selectively to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selectively to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

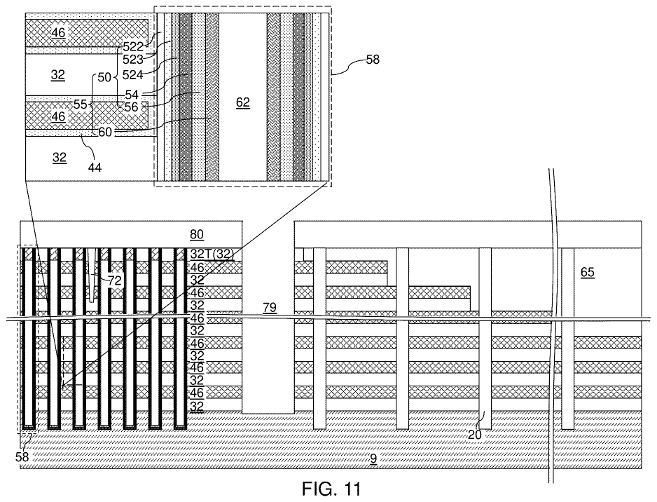

Referring to FIG. 11, an outer dielectric metal oxide blocking dielectric layer 44 can be optionally deposited by performing a conformal deposition process. The outer dielectric metal oxide blocking dielectric layer 44, if present, comprises a dielectric material that functions as an additional dielectric layer for the set of blocking dielectric layers (522, 523, 524) that includes a silicon oxide blocking dielectric layer 522, a silicon oxynitride blocking dielectric layer 523, and an inner dielectric metal oxide blocking dielectric layer 524 for the control gate electrodes (which comprise some of the electrically conductive layers) to be subsequently formed in the lateral recesses 43. In one embodiment, the outer dielectric metal oxide blocking dielectric layer 44 comprises and/or consists essentially of aluminum oxide. The outer dielectric metal oxide blocking dielectric layer 44 may be formed by a conformal deposition process, such as an atomic layer deposition process. The thickness of the outer dielectric metal oxide blocking dielectric layer 44 may be in a range from 2 nm to 4 nm, although lesser or greater thicknesses may also be employed.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser or greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

In one embodiment, each of the electrically conductive layers 46 may be formed between a respective vertically neighboring pair of the insulating layers 32 of the alternating stack (32, 46). Each vertically neighboring pair of insulating layers 32 includes a respective overlying insulating layer 32 and a respective underlying insulating layer 32. Portions of the outer dielectric metal oxide blocking dielectric layer 44 in the lateral isolation trenches 79 or over the contact-level dielectric layer 80 may be removed employing a recess etch process. In this case, for each electrically conductive layer 46 that is formed between a respective vertically neighboring pair of insulating layers 32 (i.e., an overlying insulating layer 32 and an underlying insulating layer 32, a respective outer dielectric metal oxide blocking dielectric layer 44 may be located entirely below a horizontal plane including a bottom surface of the overlying insulating layer 32 and entirely above a horizontal plane including a top surface of the underlying insulating layer 32.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

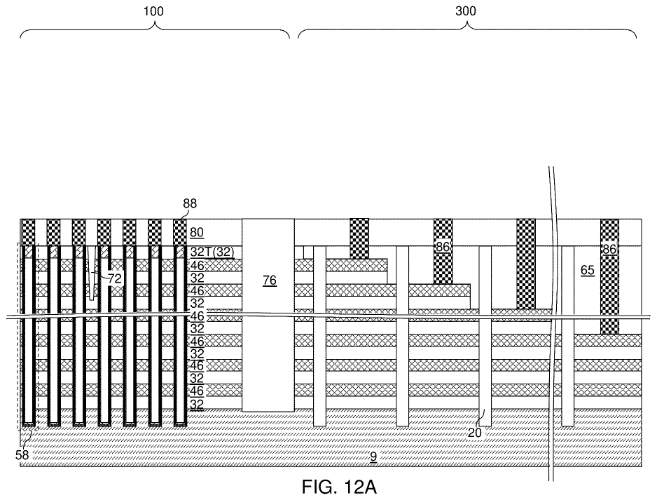

Referring to FIGS. 12A and 12B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

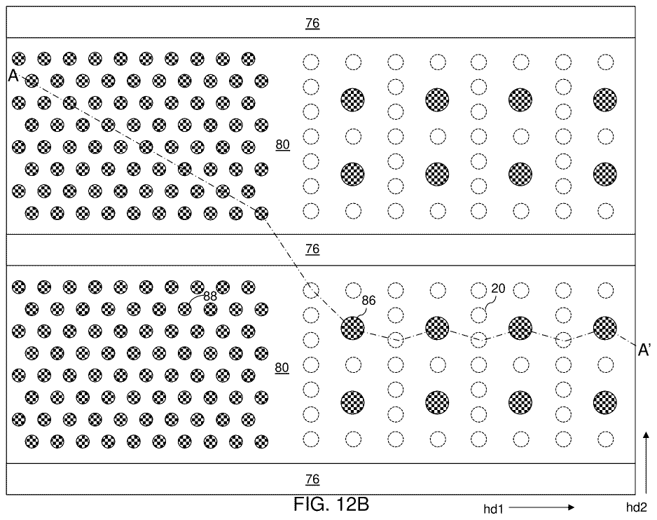

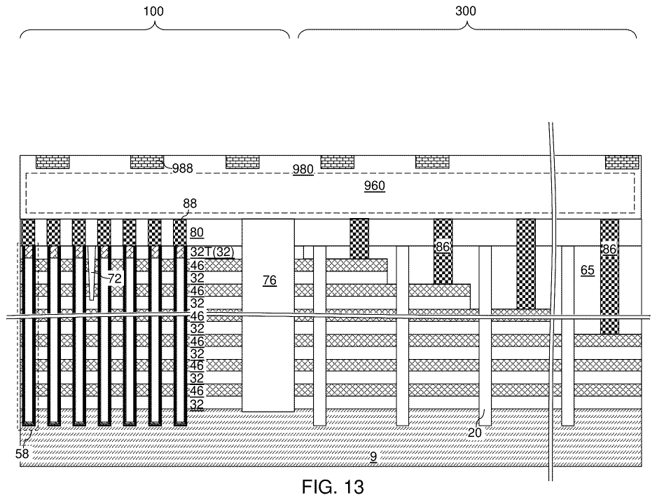

Referring to FIG. 13, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

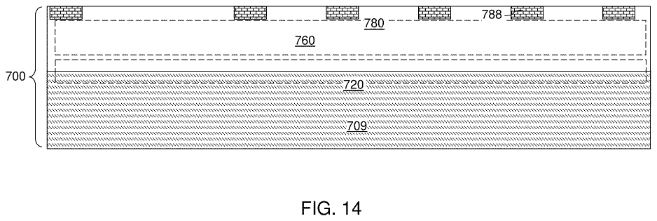

Referring to FIG. 14, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

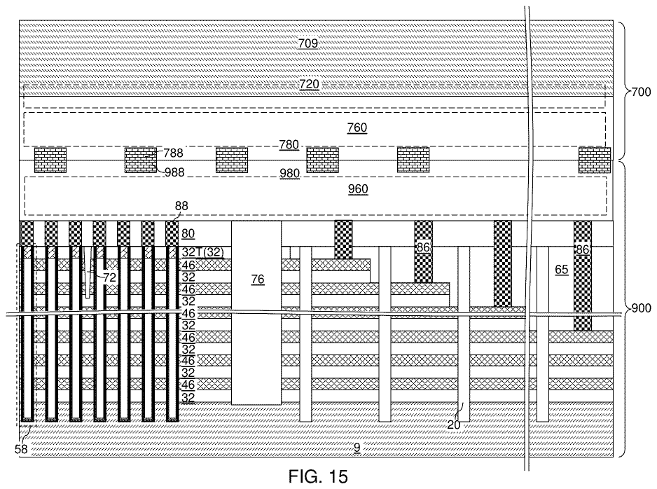

Referring to FIG. 15, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

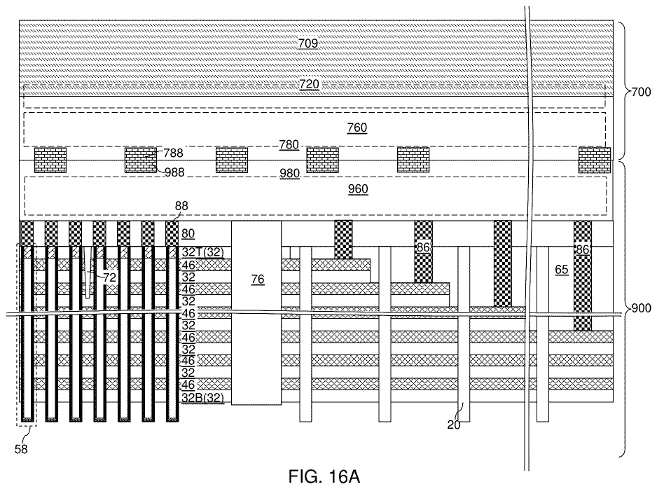

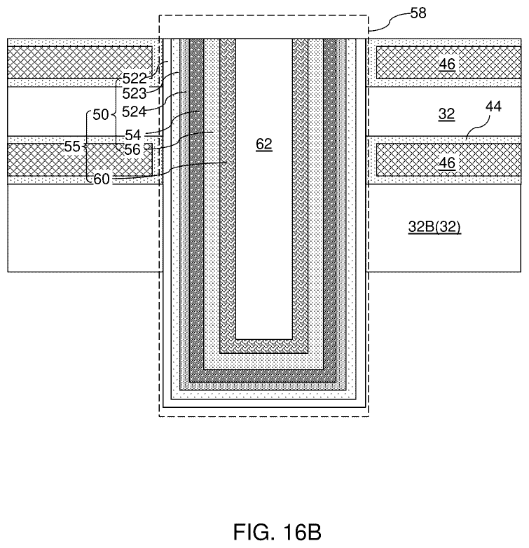

Referring to FIGS. 16A and 16B, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selectively to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH).

The entirety of the carrier substrate 9 can be removed by the selective wet etch process. Backside end surfaces of the support pillar structures 20 can be physically exposed upon removal of the carrier substrate 9. The optional outer dielectric metal oxide blocking dielectric layers 44 are illustrated in FIG. 16B, each of which embeds a respective electrically conductive layer 46. Alternatively, the optional outer dielectric metal oxide blocking dielectric layers 44 may be omitted.

Referring collectively to FIGS. 1-16B, an alternating stack (32, 46) of insulating layers and spacer material layers can be formed over a carrier substrate 9. The spacer material layers are formed as, or are subsequently replaced with, electrically conductive layers 46. Memory openings 49 extend through the alternating stack (32, 46). A memory opening fill structure 58 is formed in each memory opening 49. Each memory opening fill structure 58 comprises a memory film 50 and a vertical semiconductor channel 60.

The vertical semiconductor channel 60 may include first electrical dopants of a first conductivity type at the first atomic concentration. The carrier substrate 9 can be subsequently removed selectively to the alternating stack (32, 46).

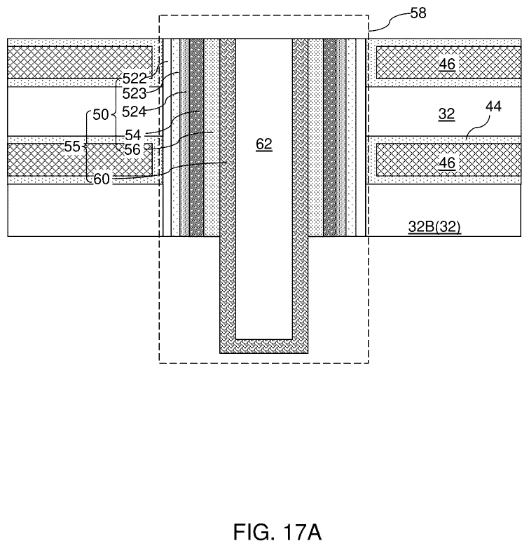

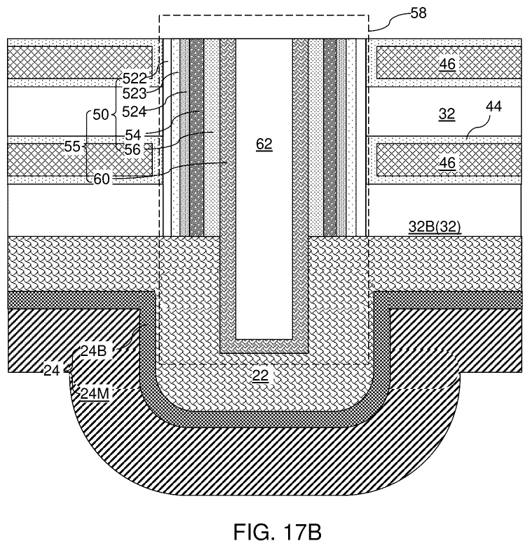

FIGS. 17A and 17B are sequential vertical cross-sectional views of a region of the first exemplary structure during formation of a source layer (22, 24) according to an embodiment of the present disclosure.

Referring to FIG. 17A, a set of etch processes can be performed to sequentially etch unmasked portions of components layers of each memory film 50 that underlie the bottommost surface of the alternating stack (32, 46). In an illustrative example, if the memory film 50 comprises a blocking dielectric stack including a silicon oxide blocking dielectric layer 522, a silicon oxynitride blocking dielectric layer 523, and an inner dielectric metal oxide blocking dielectric layer 524, and if the memory material layer 54 comprises a charge storage layer including silicon nitride, and if the tunneling dielectric layer 56 comprises a tunneling dielectric layer including an ONO stack (i.e., a stack of a first silicon oxide layer, a silicon nitride layer, and a second silicon oxide layer), the set of etch processes may comprise a first wet etch process that etches physically exposed portions of the silicon oxide blocking dielectric layer 522 and the silicon oxynitride blocking dielectric layer 523 employing dilute hydrofluoric acid, a second wet etch process that etches physically exposed portions of the inner dielectric metal oxide blocking dielectric layer 524 and the memory material layer 54 employing hot phosphoric acid, and a third chemical dry etch (CDE) process that etches the ONO stack of the tunneling dielectric layer. In one embodiment, the CDE process employs a plasma to generate reactive species that isotropically etch the exposed oxide and nitride layers of the ONO stack through chemical reactions, providing uniform material removal.

Generally, end portions of the silicon oxide blocking dielectric layer 522, the silicon oxynitride blocking dielectric layer 523, the inner dielectric metal oxide blocking dielectric layer 524, the memory material layer 54, and the tunneling dielectric layer 56 can be removed from each memory opening fill structure 58 to physically expose an end portion of a respective vertical semiconductor channel 60. The bottom surface of the bottommost insulating layer 32B may be collaterally recessed during removal of end portions of the memory films 50. In one embodiment, the bottom surface of the bottommost insulating layer 32B may be formed in a horizontal plane, below which end portions of the vertical semiconductor channels 60 extend vertically.

Referring to FIG. 17B, the first exemplary structure can be flipped upside down, and a semiconductor material layer, such as an amorphous semiconductor material layer may be conformally deposited on physically exposed surfaces of the end portion of the vertical semiconductor channels 60. The amorphous semiconductor material layer comprises an amorphous semiconductor material such as amorphous silicon. In one embodiment, the vertical semiconductor channels 60 include first electrical dopants of a first conductivity type at a first atomic concentration, and the amorphous semiconductor material layer is either undoped (i.e., intrinsic) or includes second electrical dopants of the first conductivity type at a second atomic concentration that is less than the first atomic concentration. In one embodiment, the first atomic concentration may be in a range from 1.0×10¹³/cm³ to 1.0×10¹⁶/cm³, and the second atomic concentration may be in a range from 0 to 1.0×10¹²/cm³. The thickness of the amorphous semiconductor material layer may be in a range from 10 nm to 100 nm, although lesser or greater thicknesses may also be employed. An anneal process, such as a laser anneal process, may be performed to convert the amorphous semiconductor material layer into a semiconductor source layer 22.

A metallic source layer 24 can be deposited on the physically exposed surfaces of the semiconductor source layer 22. The metallic source layer 24 can be formed directly on a bottom surface of the semiconductor source layer 22. In one embodiment, the metallic source layer 24 may comprise a metallic liner 24B and a metal layer 24M. The metallic liner 24B may contact the semiconductor source layer 22. The metal layer 24M may underlie the metallic liner 24B, and may be vertically spaced from the semiconductor source layer 22 by the metallic liner 24B. The metallic liner 24B may comprise, and/or may consist of, a conductive metallic nitride material such as TiN, TaN, MoN, and/or WN. Optionally, the metallic liner 24B may also comprise a thin metal layer such as a titanium layer. In an illustrative example, the metallic liner 24B may comprise a titanium layer that contacts the semiconductor source layer 22 and a conductive metallic nitride layer including TiN, TaN, MoN, or WN, located on the titanium layer. Alternatively, the metallic liner 24B may consist of the conductive metallic nitride layer. The thickness of the metallic liner 24B may be in a range from 3 nm to 60 nm, such as from 6 nm to 30 nm, although lesser or greater thicknesses may also be employed. The metal layer 24M may consist essentially of an elemental metal such as W, Co, Ru, Mo, Ti, Ta, etc. The thickness of the metal layer 24M may be in a range from 20 nm to 200 nm, although lesser or greater thicknesses may also be employed.

Referring to FIG. 18, the metallic source layer 24 and the semiconductor source layer 22 may be patterned, for example, by removing portions of the metallic source layer 24 and the semiconductor source layer 22 from underneath the stepped dielectric material portion 65. The combination of the semiconductor source layer 22 and the metallic source layer 24 constitutes a source layer (22, 24). In one embodiment, each vertical semiconductor channel 60 comprises a bottom end portion vertically protruding below a horizontal plane including a bottom surface of a bottommost insulating layer 32B of the insulating layers 32. In one embodiment, the source layer (22, 24) is in contact with an outer sidewall surface segment of each vertical semiconductor channel 60 and with a bottom surface of each vertical semiconductor channel 60.

Referring to FIG. 19, a backside insulating layer 26 can be deposited on the metallic source layer 24 and on the bottommost surface of the alternating stack (32, 46). Contact structures, such as source contact structures 6, may be formed through the backside insulating layer 26. Additional structures (not shown), such as bonding pads, may be formed as needed.

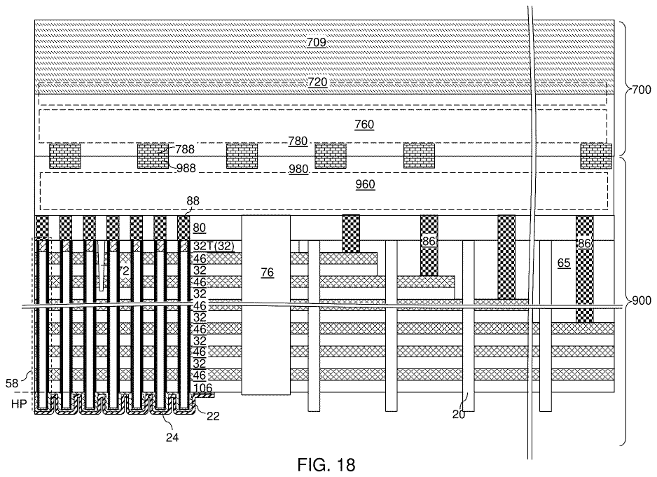

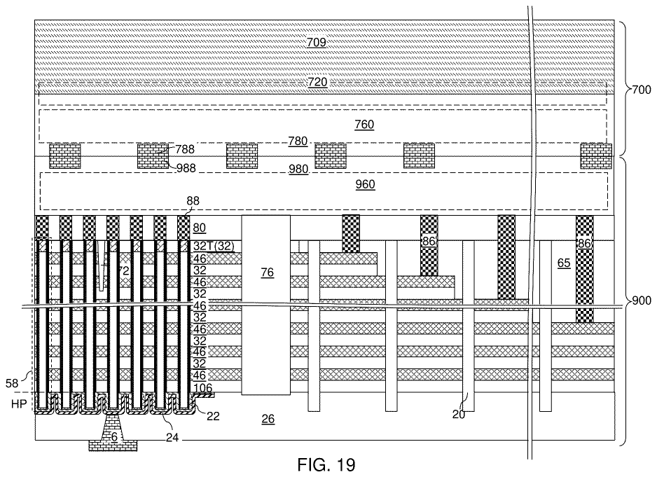

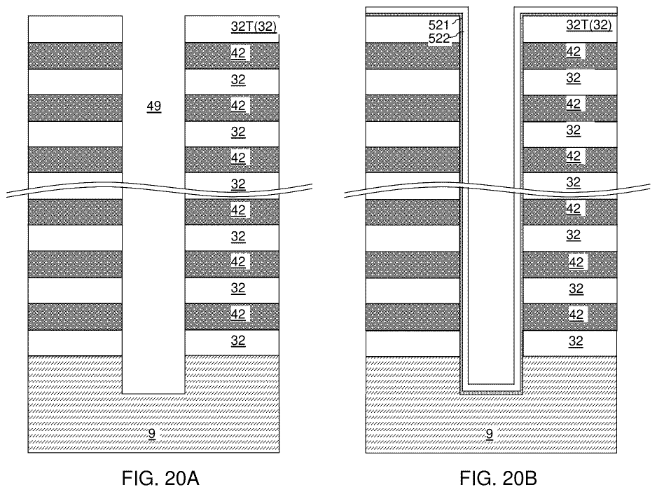

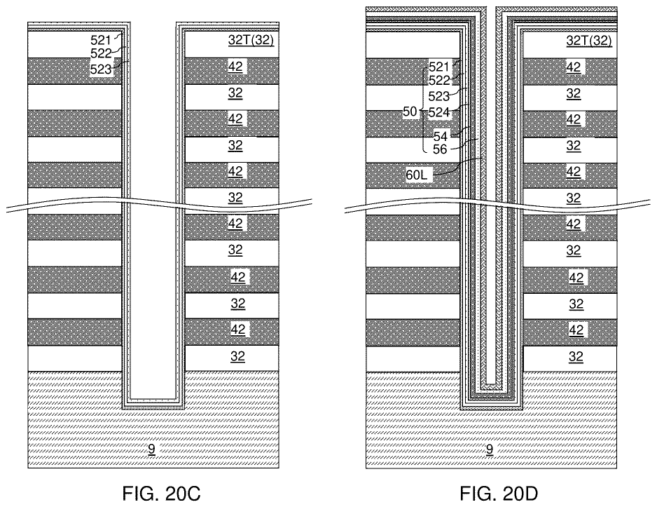

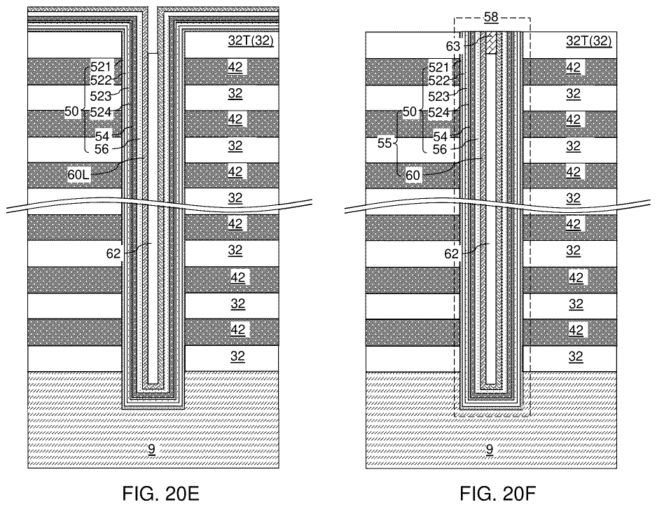

FIGS. 20A-20F are sequential vertical cross-sectional views of a memory opening 49 within a second exemplary structure during formation of a memory opening fill structure 58 according to a second embodiment of the present disclosure. In the second embodiment, the outer dielectric metal oxide blocking dielectric layer is formed in the memory opening 49 rather than in the lateral recesses 43.

Referring to FIG. 20A, a memory opening 49 in a second exemplary structure is illustrated. The second exemplary structure may be the same as the second exemplary structure illustrated in FIGS. 6A and 6B.

Referring to FIG. 20B, an outer dielectric metal oxide blocking dielectric layer 521 can be deposited by performing a conformal deposition process, such as atomic layer deposition. The outer dielectric metal oxide blocking dielectric layer 521 comprises a dielectric material that functions as a component of a blocking dielectric layer stack. In one embodiment, the outer dielectric metal oxide blocking dielectric layer 521 comprises and/or consists essentially of aluminum oxide. The thickness of the outer dielectric metal oxide blocking dielectric layer 521 may be in a range from 1 nm to 4 nm, although lesser or greater thicknesses may also be employed. The outer dielectric metal oxide blocking dielectric layer 521 can be formed entirely a peripheral portion of each memory opening 49 and vertically extends through each layer within the alternating stack (32, 42).

Subsequently, the processing steps described with reference to FIG. 7B can be performed to deposit the silicon oxide blocking dielectric layer 522. The silicon oxide blocking dielectric layer 522 in the second exemplary structure is formed directly on the outer dielectric metal oxide blocking dielectric layer 521.

Referring to FIG. 20C, the silicon oxynitride blocking dielectric layer 523 is formed by layer deposition or by nitridation of the in-process silicon oxide blocking dielectric layer 522. In the second exemplary structure, an outer sidewall of the silicon oxide blocking dielectric layer 522 can be in direct contact with an outer dielectric metal oxide blocking dielectric layer 521 at each level of the insulating layers 32 and the sacrificial material layers 42 within each memory opening 49.

Referring to FIG. 20D, the processing steps described with reference to FIG. 7D can be performed to form the inner dielectric metal oxide blocking dielectric layer 524, the memory material layer 54, the tunneling dielectric layer 56, and the semiconductor channel material layer 60L.

Referring to FIG. 20E, the processing steps described with reference to FIG. 7E can be performed to form a dielectric core 62 in each memory opening 49.

Referring to FIG. 20F, the processing steps described with reference to FIG. 7F can be performed to form a memory opening fill structure 58 in each memory opening.

Subsequently, the processing steps described with reference to FIGS. 8-10 can be performed. The processing steps described with reference to FIG. 11 can be subsequently performed with the modification of omission of formation of the outer dielectric metal oxide blocking dielectric layer 44. In this case, each electrically conductive layer 46 in the second exemplary structure can be formed directly on a horizontal bottom surface of a respective overlying insulating layer 32, on a horizontal top surface of a respective underlying insulating layer 32, and on cylindrical surface segments of outer sidewalls of outer dielectric metal oxide blocking dielectric layers 521. The processing steps described with reference to FIGS. 12A-16B can be performed thereafter.

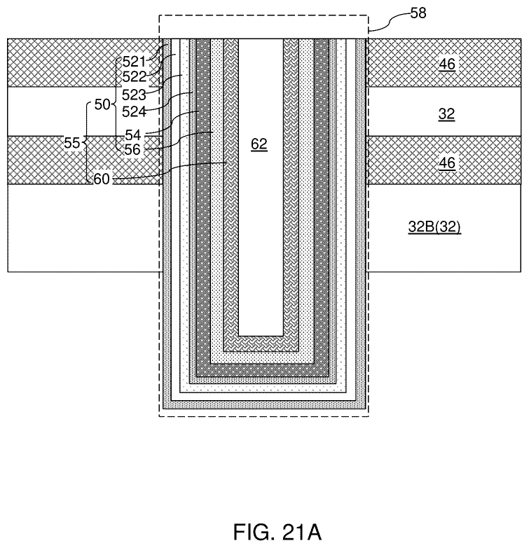

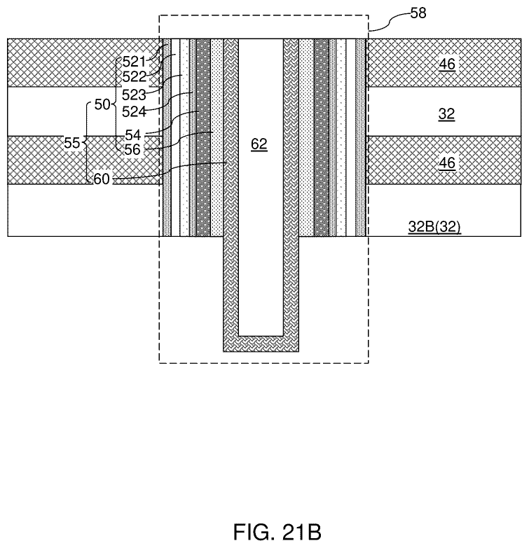

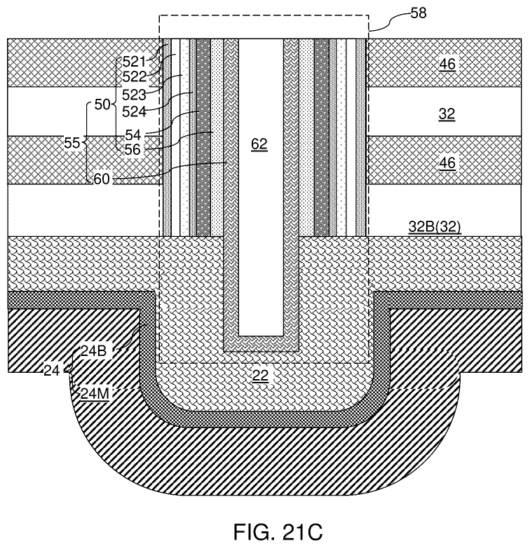

FIGS. 21A-21C are sequential vertical cross-sectional views of a region of the second exemplary structure after removal of the carrier substrate 9 and during formation of a source layer (22, 24) according to an embodiment of the present disclosure.

Referring to FIG. 21A, the second exemplary structure is illustrated after removal of the carrier substrate 9.

Referring to FIG. 21B, the processing steps described with reference to FIG. 17A can be performed with a modification in the set of etch processes. Specifically, an additional etch process can be performed to remove physically exposed portions of the outer dielectric metal oxide blocking dielectric layers 521 before removing physically exposed portions of the silicon oxide blocking dielectric layer 522, the silicon oxynitride blocking dielectric layer 523, the inner dielectric metal oxide blocking dielectric layer 524, the memory material layer 54, and the tunneling dielectric layer 56. In one embodiment, the isotropic etch process may comprise a wet etch process employing hot phosphoric acid.

Referring to FIG. 21C, the processing steps described with reference to FIG. 17B can be performed to form a semiconductor source layer 22 and a metallic source layer 24.

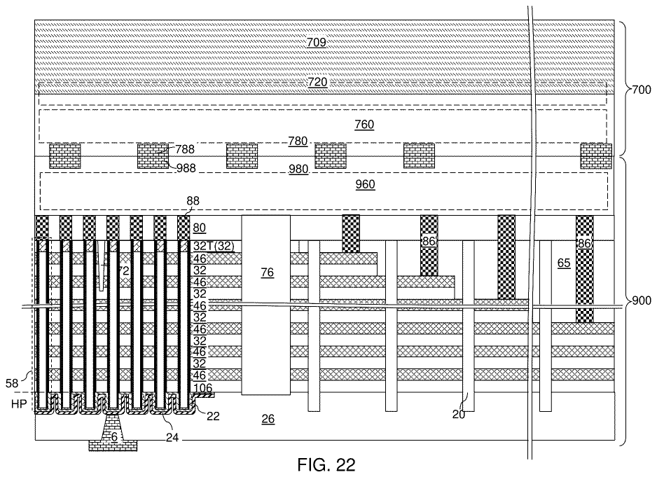

Referring to FIG. 22, the processing steps described with reference to FIG. 18 can be performed to pattern the semiconductor source layer 22 and the metallic source layer 24. A source layer (22, 24) can be formed on bottom ends of the vertical semiconductor channels 60. The processing steps described with reference to FIG. 19 can be performed to form a backside insulating layer 26 and contact structures, such as source contact structures 6.

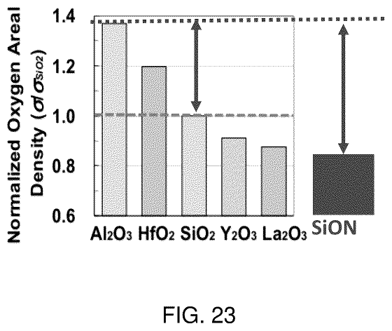

FIG. 23 is a bar graph of normalized oxygen areal density for various oxide dielectric materials. Silicon oxynitride has a lower normalized oxygen areal density than silicon oxide. If aluminum oxide or hafnium oxide is employed for the inner dielectric metal oxide blocking dielectric layer 524, oxygen ions diffuse from the inner dielectric metal oxide blocking dielectric layer 524 into the silicon oxynitride blocking dielectric layer 523, leaving oxygen vacancies in the inner dielectric metal oxide blocking dielectric layer 524. As a result, negative charges accumulate at the side of the silicon oxynitride blocking dielectric layer 523, and positive charges accumulate in the inner dielectric metal oxide blocking dielectric layer 524, creating a dipole effect at the interface.

Silicon oxynitride is a superior dipole interface material compared to silicon oxide, because silicon oxynitride has a lower normalized oxygen areal density than silicon oxide. The present inventor recognized that the greater difference in oxygen density results in higher oxygen ion diffusion from the inner dielectric metal oxide blocking dielectric layer 524 into the silicon oxynitride blocking dielectric layer 523 (than into a silicon oxide blocking dielectric), leaving a higher oxygen vacancy concentration in the inner dielectric metal oxide blocking dielectric layer 524. This leads to more negative charges accumulating at the side of the silicon oxynitride blocking dielectric layer 523, and more positive charges accumulate in the inner dielectric metal oxide blocking dielectric layer 524, creating a higher dipole effect at the interface between the inner dielectric metal oxide blocking dielectric layer 524 and the silicon oxynitride blocking dielectric layer 523, than at an interface between the inner dielectric metal oxide blocking dielectric layer 524 and a silicon oxide blocking dielectric.

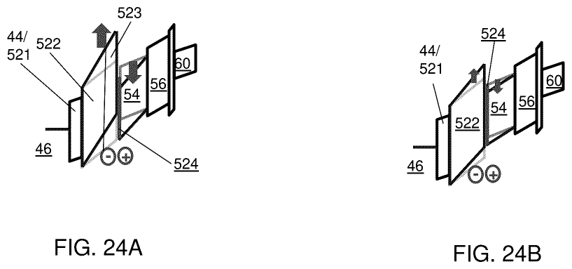

FIG. 24A illustrates a band gap diagram of the memory film 50 of the embodiment of the present disclosure and adjacent layers during a programming operation. FIG. 24B illustrates a band gap diagram of the memory film of a comparative example and adjacent layers during a programming operation. The memory film of the comparative example lacks the silicon oxynitride blocking dielectric layer 523, such that the inner dielectric metal oxide blocking dielectric layer 524 contacts the silicon oxide blocking dielectric layer 522.

The conduction band of the inner dielectric metal oxide blocking dielectric layer 524 is shifted upward, and the conduction band of the memory material layer 54 is shifted downward in both FIGS. 24A and 24B. However, the conduction band of the inner dielectric metal oxide blocking dielectric layer 524 is shifted upward, and the conduction band of the memory material layer 54 is shifted downward by a greater amount in the embodiment memory film 50 of FIG. 24A than in the memory film of the comparative example of FIG. 24B due to the presence of the silicon oxynitride blocking dielectric layer 523. This change in the band gap structure reduces electron tunneling from the memory material layer 54 to the word lines (e.g., a set of then electrically conductive layers 46) through a blocking dielectric layer stack (521/44, 522, 523, 524) during programming, thereby enhancing programming efficiency (e.g., program slope). The increased band gap shift of the embodiment memory film 50 permits the use of a thinner memory material layer 54 and results in a reduced nearest word line interference and improved fresh data retention time without a corresponding reduction in programming efficiency.

Referring to all drawings and according to various embodiments of the present disclosure, a memory device is provided, which comprises: an alternating stack (32, 46) of insulating layers 32 and electrically conductive layers 46; a memory opening 49 vertically extending through the alternating stack (32, 46); and a memory opening fill structure 58 located in the memory opening 49 and comprising, from outside to inside, a silicon oxide blocking dielectric layer 522, a silicon oxynitride blocking dielectric layer 523, an inner dielectric metal oxide blocking dielectric layer 524, a memory material layer 54, a tunneling dielectric layer 56, and a vertical semiconductor channel 60.

In one embodiment, the silicon oxynitride blocking dielectric layer 523 has a radial atomic nitrogen concentration gradient between an interface with the silicon oxide blocking dielectric layer 522 and the inner dielectric metal oxide blocking dielectric layer 524. In one embodiment, the nitrogen concentration in the silicon oxynitride blocking dielectric layer 523 decreases with a distance from the interface between the silicon oxynitride blocking dielectric layer 523 and the inner dielectric metal oxide blocking dielectric layer 524. In one embodiment, the nitrogen concentration in the silicon oxynitride blocking dielectric layer 523 is zero at an interface with the silicon oxide blocking dielectric layer 522. In one embodiment, the nitrogen concentration in the silicon oxynitride blocking dielectric layer 523 at the interface between the silicon oxynitride blocking dielectric layer 523 and the inner dielectric metal oxide blocking dielectric layer 524 is at least 15 atomic percent.

In one embodiment, the inner dielectric metal oxide blocking dielectric layer 524 consists essentially of aluminum oxide. In one embodiment, the memory material layer 54 consists essentially of silicon nitride.

In one embodiment, an outer sidewall of the silicon oxide blocking dielectric layer 522 is in direct contact with the outer dielectric metal oxide blocking dielectric layer (521/44) at a level of one of the electrically conductive layers 46. In the second embodiment, the outer dielectric metal oxide blocking dielectric layer 521 is located entirely within the memory opening 49 and vertically extends through each electrically conductive layer 46 within the alternating stack (32, 46). In the first embodiment, said one of the electrically conductive layers 46 is located between a vertically neighboring pair of the insulating layers 32 of the alternating stack (32, 46), the vertically neighboring pair of insulating layers 32 including an overlying insulating layer 32 and an underlying insulating layer 32; and the outer dielectric metal oxide blocking dielectric layer 44 is located entirely below a horizontal plane including a bottom surface of the overlying insulating layer 32 and entirely above a horizontal plane including a top surface of the underlying insulating layer 32. In one embodiment, the outer dielectric metal oxide blocking dielectric layer (521/44) consists essentially of aluminum oxide. In one embodiment, an inner sidewall of the silicon oxynitride blocking dielectric layer 523 is in direct contact with an outer sidewall of the inner dielectric metal oxide blocking dielectric layer 524.

In one embodiment, the memory device also includes a source layer (22, 24) underlying the alternating stack (32, 46) and contacting a bottom end of the vertical semiconductor channel 60; and a drain region 63 contacting a top end of the vertical semiconductor channel 60.

In one embodiment, the source layer (22, 24) comprises a horizontally-extending portion contacting a bottom surface of a bottommost insulating layer 32B of the insulating layers 32. In one embodiment, the vertical semiconductor channel 60 comprises a bottom end portion vertically protruding below a horizontal plane including a bottom surface of a bottommost insulating layer 32B among the insulating layers 32; and the source layer (22, 24) is in contact with an outer sidewall surface segment of the vertical semiconductor channel 60 and with a bottom surface of the vertical semiconductor channel 60.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers;
a memory opening vertically extending through the alternating stack; and
a memory opening fill structure located in the memory opening and comprising, from outside to inside, a silicon oxide blocking dielectric layer, a silicon oxynitride blocking dielectric layer, an inner dielectric metal oxide blocking dielectric layer, a memory material layer, a tunneling dielectric layer, and a vertical semiconductor channel.

2. The memory device of claim 1, wherein the silicon oxynitride blocking dielectric layer has a radial atomic nitrogen concentration gradient between an interface with the silicon oxide blocking dielectric layer and the inner dielectric metal oxide blocking dielectric layer.

3. The memory device of claim 2, wherein the nitrogen concentration in the silicon oxynitride blocking dielectric layer decreases with a distance from the interface between the silicon oxynitride blocking dielectric layer and the inner dielectric metal oxide blocking dielectric layer.

4. The memory device of claim 3, wherein the nitrogen concentration in the silicon oxynitride blocking dielectric layer is zero at an interface with the silicon oxide blocking dielectric layer.

5. The memory device of claim 3, wherein the nitrogen concentration in the silicon oxynitride blocking dielectric layer at the interface between the silicon oxynitride blocking dielectric layer and the inner dielectric metal oxide blocking dielectric layer is at least 15 atomic percent.

6. The memory device of claim 1, wherein the inner dielectric metal oxide blocking dielectric layer consists essentially of aluminum oxide.

7. The memory device of claim 6, wherein the memory material layer consists essentially of silicon nitride.

8. The memory device of claim 1, further comprising an outer dielectric metal oxide blocking dielectric layer, wherein an outer sidewall of the silicon oxide blocking dielectric layer is in direct contact with the outer dielectric metal oxide blocking dielectric layer at a level of one of the electrically conductive layers.

9. The memory device of claim 8, wherein the outer dielectric metal oxide blocking dielectric layer is located entirely within the memory opening and vertically extends through each electrically conductive layer within the alternating stack.

10. The memory device of claim 8, wherein:
said one of the electrically conductive layers is located between a vertically neighboring pair of the insulating layers of the alternating stack, the vertically neighboring pair of insulating layers including an overlying insulating layer and an underlying insulating layer; and
the outer dielectric metal oxide blocking dielectric layer is located entirely below a horizontal plane including a bottom surface of the overlying insulating layer and entirely above a horizontal plane including a top surface of the underlying insulating layer.

11. The memory device of claim 8, wherein the outer dielectric metal oxide blocking dielectric layer consists essentially of aluminum oxide.

12. The memory device of claim 1, wherein an inner sidewall of the silicon oxynitride blocking dielectric layer is in direct contact with an outer sidewall of the inner dielectric metal oxide blocking dielectric layer.

13. The memory device of claim 1, further comprising:
a source layer underlying the alternating stack and contacting a bottom end of the vertical semiconductor channel; and
a drain layer contacting a top end of the vertical semiconductor channel.

14. The memory device of claim 13, wherein:
the vertical semiconductor channel comprises a bottom end portion vertically protruding below a horizontal plane including a bottom surface of a bottommost insulating layer of the insulating layers; and
the source layer is in contact with an outer sidewall surface segment of the vertical semiconductor channel and with a bottom surface of the vertical semiconductor channel.

15. A method of forming a memory device, comprising:
forming an alternating stack of insulating layers and spacer material layers over a carrier substrate, wherein the spacer material layers are formed as, or are subsequently replaced with, electrically conductive layers;
forming a memory opening through the alternating stack; and
forming a memory opening fill structure in the memory opening by sequentially forming a silicon oxide blocking dielectric layer, a silicon oxynitride blocking dielectric layer, an inner dielectric metal oxide blocking dielectric layer, a memory material layer, a tunneling dielectric layer, and a vertical semiconductor channel.

16. The method of claim 15, further comprising:
depositing an in-process silicon oxide blocking dielectric layer in the memory opening; and
performing a nitridation process that nitrides an inner surface portion of the in-process silicon oxide blocking dielectric layer, wherein an outer portion of the in-process silicon oxide blocking dielectric layer that is not nitrided during the nitridation process constitutes the silicon oxide blocking dielectric layer, and an inner portion of the in-process silicon oxide blocking dielectric layer that is nitrided during the nitridation process constitutes the silicon oxynitride blocking dielectric layer.

17. The method of claim 16, wherein:
the silicon oxynitride blocking dielectric layer is formed with a radial atomic nitrogen concentration gradient; and
the nitrogen concentration in the silicon oxynitride blocking dielectric layer decreases with a distance from an interface between the silicon oxynitride blocking dielectric layer and the inner dielectric metal oxide blocking dielectric layer upon formation of the inner dielectric metal oxide blocking dielectric layer.

18. The method of claim 15, wherein the inner dielectric metal oxide blocking dielectric layer consists essentially of aluminum oxide.

19. The method of claim 15, further comprising forming an outer dielectric metal oxide blocking dielectric layer that contacts the silicon oxide blocking dielectric layer.

20. The method of claim 15, further comprising:
removing the carrier substrate;
removing end portions of the silicon oxide blocking dielectric layer, the silicon oxynitride blocking dielectric layer, the inner dielectric metal oxide blocking dielectric layer, the memory material layer, and the tunneling dielectric layer to physically expose an end portion of the vertical semiconductor channel; and
forming a source layer on the end portion of the vertical semiconductor channel.
